(19) United States
(12) Patent Application Publication
(10) Pub. No.: US 2017/0110622 A1
(43) Pub. Date: Apr. 20, 2017

(54) APPARATUS FOR ELECTROPLATING OF ELECTRODES ON PHOTOVOLTAIC STRUCTURES

(71) Applicant: SolarCity Corporation, San Mateo, CA (US)

(72) Inventors: Nicholas G. J. de Vries, Alameda, CA (US); Zhi-Wen Sun, Sunnyvale, CA (US)

(73) Assignee: SolarCity Corporation, San Mateo, CA (US)

(21) Appl. No.: 15/294,183

(22) Filed: Oct. 14, 2016

Related U.S. Application Data
(60) Provisional application No. 62/241,598, filed on Oct. 14, 2015.

(51) Int. Cl. H01L 31/18; C25D 17/00; C25D 17/08; H01L 21/687; C25D 7/12

(52) U.S. Cl. CPC H01L 31/1876; H01L 21/68735; H01L 21/68728; C25D 7/12; C25D 17/08; C25D 17/007; C25D 17/005; C25D 17/001

(57) ABSTRACT

A wafer-holding apparatus for electroplating of a solar cell wafer is provided. The wafer has chamfered corners and comprises a plurality of busbar areas, wherein at least one busbar area is near an edge of the wafer. The wafer-holding apparatus includes a plurality of wafer-holding mechanisms for maintaining contact with a wafer. One of the plurality of wafer-holding mechanisms can be longer than at least one other wafer-holding mechanism, thereby facilitating secure contact with the busbar area near the edge of the wafer, which is shorter than other busbar areas on the wafer due to the chamfered corners.

### CROSS-REFERENCE TO OTHER APPLICATIONS

This claims the benefit of U.S. Provisional Patent Application No. 62/241,598, Attorney Docket Number P193-1PUS, entitled “APPARATUS FOR ELECTROPLATING OF ELECTRODES ON PHOTOVOLTAIC STRUCTURES,” filed Oct. 14, 2015, the disclosure of which is incorporated herein by reference in its entirety for all purposes.

### FIELD OF INVENTION

This is generally related to an apparatus for electroplating of electrodes on photovoltaic structures.

### DEFINITIONS

“Solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

“Finger lines,” “finger electrodes,” and “fingers” refer to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or solar cell strip. A photovoltaic structure is not limited to a device fabricated by a particular method. For example, a photovoltaic structure can be a crystalline silicon-based solar cell, a thin film solar cell, an amorphous silicon-based solar cell, a poly-crystalline silicon-based solar cell, or a strip thereof.

### BACKGROUND

One way of fabricating electrodes on a photovoltaic structure is to electroplate a metal grid, which can include one or more metal layers, directly on the photovoltaic structure or on a transparent conductive oxide (TCO) layer. The electroplated metal grid can provide lower resistance at a lower cost than the traditional material (such as Ag and Al). In large-scale solar cell fabrications, throughput in the electroplating process can be a key in reducing the overall fabrication cost.

### SUMMARY

A wafer-holding apparatus for electroplating of a solar cell wafer is provided. The wafer has chamfered corners and comprises a plurality of busbar areas, wherein at least one busbar area is near an edge of the wafer. The wafer-holding apparatus includes a plurality of wafer-holding mechanisms for maintaining contact with a wafer. One of the plurality of wafer-holding mechanisms can be longer than at least one other wafer-holding mechanism, thereby facilitating secure contact with the busbar area near the edge of the wafer, which is shorter than other busbar areas on the wafer due to the chamfered corners.

Alternatively, the wafer-holding mechanism can be of substantially equal length. A respective wafer-holding mechanism can have a front piece and a back piece configured to be in contact with a front surface and a back surface of the wafer, respectively. The front piece of the wafer-holding mechanism can be narrower than the back piece.

In another embodiment, each wafer-holding mechanism can have a wafer clamp. The apparatus can have a first tab and a second tab. The first tab can be connected to the clamps on a first side. The second tab can be connected to the clamps on a second side. The first tab and second tab can be coupled by at least one spring, thereby allowing the clamps to be opened together.

### BRIEF DESCRIPTION OF THE FIGURES

FIG. 1 shows an exemplary photovoltaic structure with electroplated metal grids, according to an embodiment of the present invention.

FIG. 2A shows a top view of an electroplating system (prior art).

FIG. 2B shows a cross-sectional view of a conventional electroplating system (prior art).

FIG. 3A shows an exemplary solar cell with two busbars (prior art).

FIG. 3B shows the surface of an exemplary bifacial solar cell with a single center busbar, according to an embodiment of the present invention.

FIG. 3C shows a cross-sectional view of the bifacial solar cell with a single center busbar per surface, according to an embodiment of the present invention.

FIG. 3D shows the front surface of an exemplary bifacial solar cell, according to an embodiment of the present invention.

FIG. 3E shows the back surface of a solar cell, according to an embodiment of the present invention.

FIG. 3F shows a cross-sectional view of a bifacial solar cell, according to an embodiment of the present invention.

FIG. 4 shows a solar cell string with each solar cell being divided into multiple smaller cells, according to an embodiment of the present invention.

FIG. 5A shows an exemplary metallic grid pattern on the front surface of a solar cell, according to an embodiment of the present invention.

FIG. 5B shows an exemplary metallic grid pattern on the back surface of a solar cell, according to an embodiment of the present invention.

FIG. 6 shows an electroplating system according to an embodiment of the present invention.

FIG. 7 shows an example of a bifacial solar cell being held by a set of holding mechanisms, according to one embodiment of the present invention.

FIG. 8 shows another example of a bifacial solar cell being held by a set of holding mechanisms, according to one embodiment of the present invention.

FIG. 9 shows an exemplary holding mechanism, according to an embodiment of the present invention.

FIG. 10 shows exemplary holding mechanisms, according to an embodiment of the present invention.

FIG. 11 shows another example of holding mechanisms, according to an embodiment of the present invention.

FIG. 12A shows a frontal view of a holding mechanism, and FIG. 12B shows a side view of the holding mechanism, according to one embodiment of an invention.

FIG. 13 shows an exemplary busbar layout for accommodating the contact of a holding mechanism, according to one embodiment of the present invention.

FIG. 14A shows exemplary wafer-holding mechanisms, according to an embodiment of the present invention.

FIG. 14B shows another view of the wafer-holding mechanisms shown in FIG. 14A, according to an embodiment of the present invention.

FIG. 15 shows another example of the wafer-holding mechanisms, according to an embodiment of the present invention.

FIG. 16 provides another view of the wafer-holding jig shown in FIG. 15, according to one embodiment of the present invention.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention provide a high-throughput electroplating apparatus that facilitates electroplating of metal onto a psuedo-square wafer of a photovoltaic structure that can be divided into a number of strips. More specifically, the electroplating apparatus includes conductive wafer-holding mechanisms that can be placed at locations where busbars are while accommodating the chambered corners of a pseudo-square wafer. In addition, these wafer-holding mechanisms can be fixed on a belt, which can continuously carry the wafers through an electroplating bath, thereby achieving a high throughput.

### Electroplating System for Solar Cell Fabrication

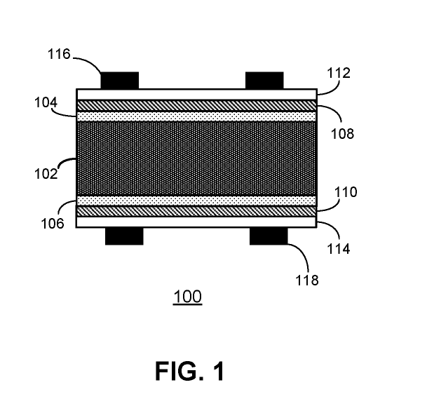

It has been shown that, for solar cell applications, electroplated metal grids can offer lower resistivity compared with printed Ag grids, which include low-temperature-cured silver paste layers. For example, a metal grid that includes one or more electroplated Cu layers may have a resistivity equal to or less than 5×10⁻⁶ Ω·cm. FIG. 1 shows an exemplary photovoltaic structure with electroplated metal grids, according to an embodiment of the present invention. In the example shown in FIG. 1, photovoltaic structure 100 can be a double-sided tunneling junction solar cell. More specifically, photovoltaic structure 100 can includes base layer 102, quantum tunneling barrier (QTB) layers 104 and 106 that cover both surfaces of base layer 102 and passivate the surface-defect states, front-side doped a-Si layer forming front surface-field layer 108, back-side doped a-Si layer forming back-side emitter layer 110, front transparent conducting oxide (TCO) layer 112, back TCO layer 114, front-side electroplated metal grid 116, and back-side electroplated metal grid 118. Note that a similar photovoltaic structure can have an emitter layer positioned at the front side and a back surface-field layer positioned on the back side. In addition to the tunneling junction solar cells, the electroplated metal grids can also be incorporated with other types of photovoltaic structures, such as diffusion based solar cells. Detailed descriptions of fabricating solar cells with electroplated metal grids can be found in U.S. patent application Ser. No. 12/835,670 (Attorney Docket No. P52-1NUS), entitled “SOLAR CELL WITH METAL GRID FABRICATED BY ELECTROPLATING,” by inventors Jianming Fu, Zheng Xu, Chentao Yu, and Jiunn Benjamin Heng, filed Jul. 13, 2010, and U.S. patent application Ser. No. 13/220,532 (Attorney Docket No. P59-1NUS), entitled “SOLAR CELL WITH ELECTROPLATED METAL GRID,” by inventors Jianming Fu, Zheng Xu, Chentao Yu, and Jiunn Benjamin Heng, filed Aug. 29, 2011, the disclosures of which are herein incorporated by reference in their entirety.

In an electroplating process, work pieces (the parts to be plated) can be electrically coupled to a cathode, and the metal to be plated (such as Cu and Ni) forms the anode. To facilitate the flow of current, all components, including the anode and the work pieces, can be submerged in a suitable electrolyte solution, and a voltage can be applied between the anode and the cathode. For a large-scale fabrication of photovoltaic structures, the electrolyte solution along with the anode can be placed in a large tank, forming an electrolyte bath, and work pieces (in this case solar cells) connecting to a moving cathode can sequentially enter the bath from one end and are plated while they move from one end of the tank to the other. The moving speed and/or plating voltage can be controlled based on the desired plating thickness. The plated photovoltaic structure can be taken out of the bath after they reach the other end while new photovoltaic structures continuously enter the bath. To ensure plating uniformity, the electrolyte solution can be circulated and filtered.

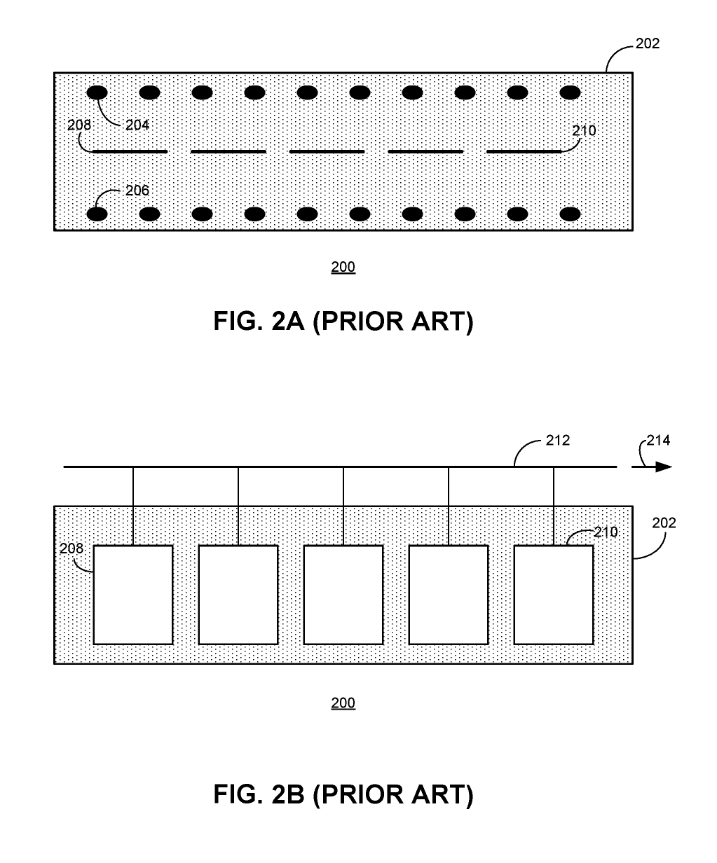

FIG. 2A shows a top view of an electroplating system (prior art). In this example, electroplating system 200 can include a rectangular tank 202 filled with electrolyte solution, a number of anodes (such as anodes 204 and 206) positioned on both sides of tank 202, and a number of wafer-holding jigs, such as jigs 208 and 210, submerged in the electrolyte solution. Each jig can hold one or more wafers. Note that the wafer-holding jigs provide not only mounting places for the to-be-plated wafers but also electrical connections between the plating surfaces (in this case, both side of the wafers) and the cathode (not shown in FIG. 2B), thus enabling metal ions to be deposited onto the plating surfaces. In the system shown in FIGS. 2A and 2B, the jigs can be placed in the bath form a single line, with each jig providing two plating surfaces (the front surface and the back surface). With a certain design, both sides of the photovoltaic structures mounted on a jig can be electroplated simultaneously. For example, both the front and back surfaces of a solar cell can include conducting portions that are electrically connected to the cathode and are exposed to the electrolyte solution. Hence, these conducting portions of both surfaces can be plated simultaneously.

FIG. 2B shows a cross-sectional view of a conventional electroplating system (prior art). In this example, the wafer-holding jigs, such as jigs 208 and 210, can be attached to cathode 212 and are submerged in the electrolyte solution inside tank 202. During plating, cathode 212, and hence the jigs and wafers mounted on the jigs, can move along the longer edger of tank 202, as indicated by arrow 214, and both sides of the wafers can be plated during the process. Depending on the desired plating thickness, various parameters, such as the moving speed of the jigs and the voltage applied between the cathode and the anodes, can be adjusted.

Electroplating system 200 shown in FIGS. 2A and 2B allows continuous, simultaneous plating of a plurality of wafers, and hence can be used for high-throughput fabrication of solar cells. However, such a system often occupies a large space (due to the size of the tank, which can be up to 50 m long), and a large-scale solar cell manufacturing facility may need to accommodate many such systems. In addition, building and maintaining such systems can also be costly. Therefore, it is desirable to improve the throughput of each electroplating system in order to reduce the number of needed equipments and to save space and cost.

It is possible to improve the plating throughput by increasing the number of lanes of wafers in the plating bath. More details of such a system can be found U.S. patent application Ser. No. 14/286,841 (Attorney Docket No. P68-1NUS), entitled “ELECTROPLATING APPARATUS WITH IMPROVED THROUGHPUT,” by inventors Jianming Fu and Wen Zhong Kong, filed May 23, 2014, the disclosure of which is incorporated by reference in its entirety herein.

### Electrode Design

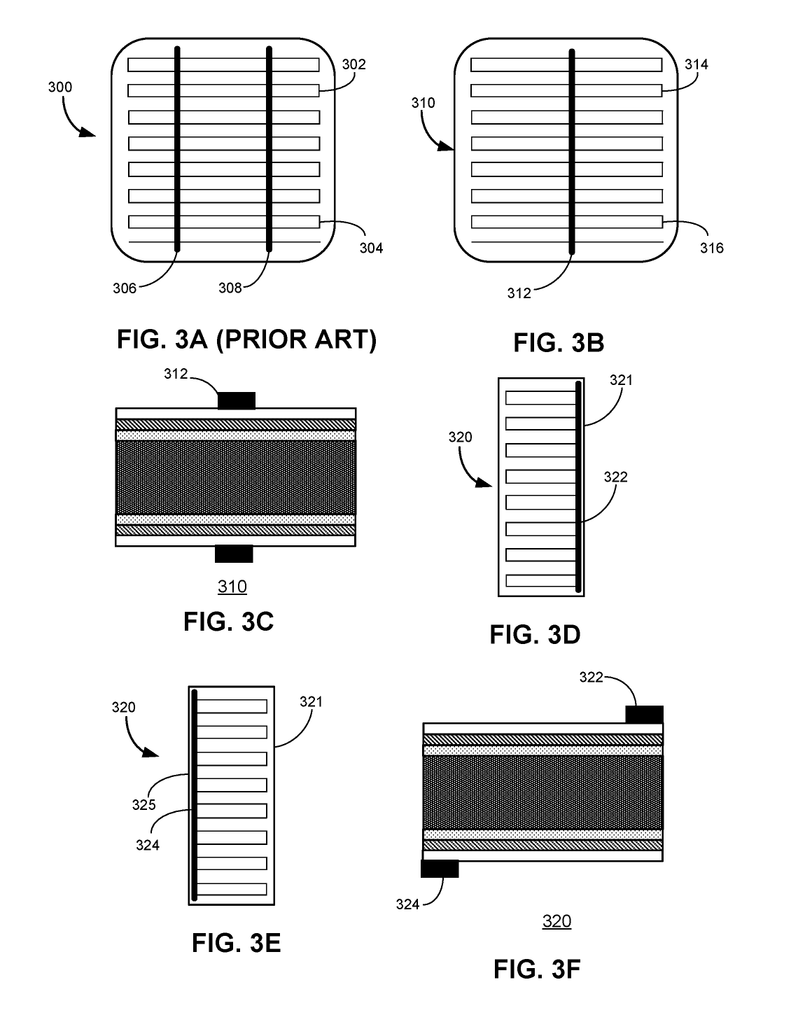

One factor in the electrode design is the balance between the increased resistive losses associated with a widely spaced grid and the increased reflection and shading effect caused by the amount of metal coverage of the surface. In conventional solar cells, to mitigate power loss due to series resistance of the finger lines, two busbars are typically used, as shown in FIG. 3A. For 5-inch solar cells (which can be 5 inch×5 inch squares or pseudo squares with rounded corners), there are two busbars on each surface. For larger, 6-inch solar cells (which can be 6 inch×6 inch squares or pseudo squares with rounded corners), three or more busbars may be used depending on the resistivity of the electrode materials. In the example illustrated in FIG. 3A, the surface (which can be the front or back surface) of solar cell 300 can includes a plurality of parallel finger lines, such as finger lines 302 and 304, and two busbars 306 and 308 placed perpendicular to the finger lines. The busbars can be positioned in such a way as to ensure that the distance (and hence the resistance) from any point on a finger to a busbar is sufficiently small to mitigate power loss. However, these two busbars and the metal ribbons subsequently soldered onto these busbars for inter-cell connections can create a significant amount of shading, which reduces the solar cell performance.

In some embodiments of the present invention, the front and back metal grids, such as the finger lines, can include electroplated Cu lines. By using an electroplating or electroless plating technique, one can obtain Cu grid lines with a resistivity of equal to or less than 5×10⁻⁶ Ω·cm. In addition, a metal seed layer (such as Cu or Ti) can be deposited directly on the TCO layer using, for example, a physical vapor deposition (PVD) process. This seed layer can ensure excellent ohmic contact with the TCO layer as well as a strong physical bond with the solar cell structure. Subsequently, the Cu grid can be electroplated onto the seed layer. This two-layer (seed layer and electroplated Cu layer) can facilitate excellent ohmic contact quality, physical strength, low cost, and facilitates large-scale manufacturing.

The reduced resistance of the Cu fingers makes it possible to reduce the number of busbars on the solar cell surface. In some embodiments of the present invention, a single busbar can be used to collect the current from the fingers.

FIG. 3B shows the surface of an exemplary bifacial solar cell with a single center busbar, according to an embodiment of the present invention. In FIG. 3B, the front or back surface of solar cell 310 can includes a single busbar 312 and a number of finger lines, such as finger lines 314 and 316. FIG. 3C shows a cross-sectional view of the bifacial solar cell with a single center busbar per surface, according to an embodiment of the present invention. The semiconductor multilayer structure shown in FIG. 3C can be similar to the one shown in FIG. 2. Note that the finger lines are not shown in FIG. 3C because the cut plane is between two finger lines. In the example shown in FIG. 3C, busbar 312 can run in the direction that is perpendicular to the paper, and the finger lines can run from left to right. Because there is only one busbar on each surface, the distances from the edges of the fingers to the busbar are longer. However, the elimination of one busbar can reduce shading, which not only can compensate for the power loss caused by the increased finger-to-busbar distance, but also can provide additional power gain. FIG. 3D shows the front surface of an exemplary bifacial solar cell, according to an embodiment of the present invention. In this example, the front surface of a cut solar cell 320 can include a number of finger lines and single busbar 322, which is positioned adjacent to edge 321 of solar cell 320. Busbar 322 is in contact with the rightmost end of all the finger lines, and can collect current from all the finger lines. FIG. 3E shows the back surface of solar cell 320. The back surface of solar cell 320 can include a number of finger lines and single busbar 324, which is positioned adjacent to edge 325 that is opposite to edge 321. Similar to busbar 322, busbar 324 is in contact with the leftmost end of all the finger lines. FIG. 3F shows a cross-sectional view of bifacial solar cell 320. The photovoltaic structure shown in FIG. 3F can be similar to the one shown in FIG. 2. Like FIG. 3C, in FIG. 3F, the finger lines (not shown) run from left to right, and the busbars run in the direction that is perpendicular the paper. As illustrated in FIGS. 3D-3F, the busbars on the front and the back surfaces of bifacial solar cell 320 can be placed adjacent to opposite edges of the cell. This configuration can further improve power gain because the busbar-induced shading now occurs at locations that were less effective in energy production.

The single busbar configurations (either the center busbar or the edge busbar) not only can provide power gain, but also can reduce fabrication cost, because less metal will be needed. Moreover, the metal finger lines can have a cross-section with a curved profile to deflect incident light that otherwise would be blocked onto the cell surface, thus further reducing the shading effect. For bifacial operation, both the front and back covers of a solar panel can be transparent. These covers can be made from glass or polymer. Such bifacial panels can absorb light from both the “front” (facing sunlight) and “back” (facing away from the sunlight) surfaces, which allows the cell to convert both direct and indirect sunlight. Indirect sunlight can include reflected, deflected, and diffused sunlight from various surfaces surrounding the panel. Such bifacial solar panels are particularly useful in settings where the panels are elevated from a flat surface, such as in a solar farm environment.

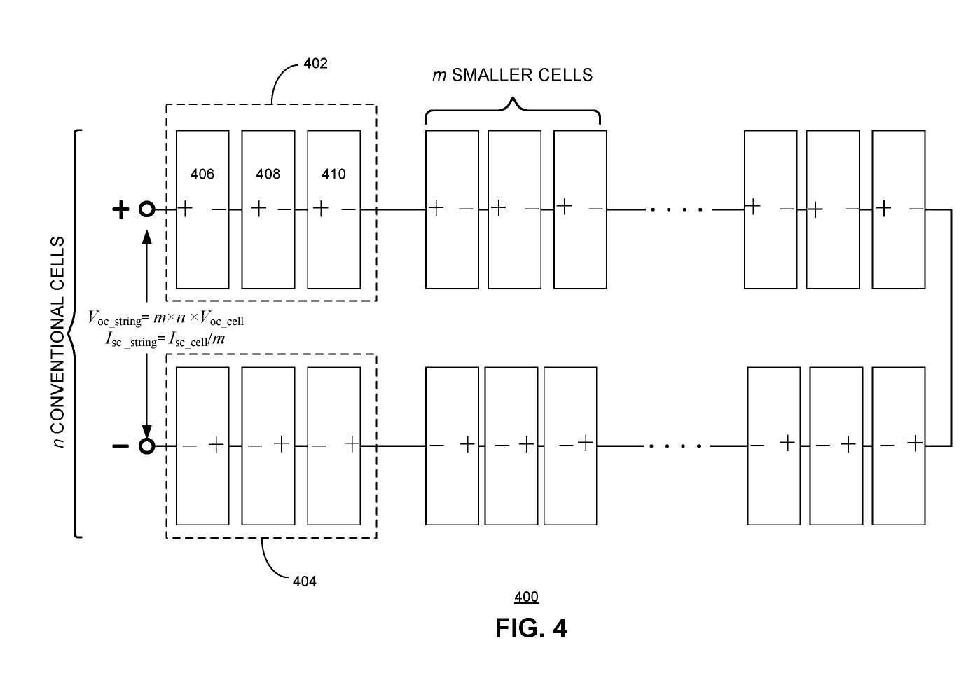

One of the goals when designing a solar panel is to extract as much power as possible from the solar cells within the panel. Generally, the lower the total internal resistance the entire panel has, the more power can be extracted from the panel. One way to reduce the total internal resistance of a solar panel is to divide a square or pseudo-square shaped solar cell into a number of strips, and interconnect the resulting strips in a specific pattern. FIG. 4 shows a solar cell string with each solar cell being divided into multiple smaller cells, according to an embodiment of the present invention. In this example, solar cell string 400 includes a number of smaller cells. A conventional solar cell (such as the one represented by dotted line 402) is replaced by a number of serially connected strips (which can be obtained by dividing a regular solar cell), such as strips 406, 408, and 410. For example, if the conventional solar cell is a 6-inch pseudo-square cell, each strip can have a dimension of approximately 2-inch by 6-inch, and a conventional 6-inch pseudo-square cell can be replaced by three 2-inch by 6-inch strips connected in series. Note that, as long as the semiconductor-layer structure of the strips remains the same as the conventional square-sized solar cell, the strips can have the same open-circuit voltage (V_{oc}) as that of an undivided solar cell. On the other hand, the current generated by each strip is a fraction of that of the original undivided cell due to its reduced size. Hence, the output current by solar cell string 400 is a fraction of the output current by a conventional solar cell string with undivided cells. The output voltage of the solar cell strings is now three times that of a solar string with undivided cells, thus making it possible to have parallelly connected strings without sacrificing the output voltage.

Now assuming that the open circuit voltage (V_{oc}) across a standard 6-inch solar cell is V_{oc}_{_}_{cell}, then the V_{oc} of each string is m×n×V_{oc}_{_}_{cell}, wherein m is the number of smaller cells as the result of dividing a conventional square shaped cell, and n is the number of conventional cells included in each string. On the other hand, assuming that the short circuit current (I_{sc}) for the standard 6-inch solar cell is I_{sc}_{_}_{cell}, then the I_{sc} of each string is I_{sc}_{_}_{cell}/m. Hence, when m such strings are connected in parallel in a new panel configuration, the V_{oc} for the entire panel can be the same as the V_{oc} for each string, and the I_{sc} for the entire panel will be the sum of the I_{sc} of all strings. More specifically, with such an arrangement, one can achieve: V_{oc}_{_}ₚₐₙₑₗ=m×n×V_{oc}_{_}_{cell} and I_{sc}_{_}ₚₐₙₑₗ=I_{sc}_{_}_{cell}. This means that the output voltage and current of this new solar panel can be comparable to the output voltage and current of a conventional solar panel of a similar size but with undivided solar cells all connected in series. The similar voltage and current outputs make this new panel compatible with other devices, such as inverters, that are used by a conventional solar panel with all its undivided cells connected in series. Although having similar current and voltage output, the new solar panel can extract more output power to external load because of the reduced total internal resistance. In one embodiment, the strips can have an electrode design as shown in FIGS. 3D and 3E, and a string can be formed by cascading multiple strips. More details on solar panels based on cascaded strips can be found in U.S. patent application Ser. No. 14/563,867 (Attorney Docket No. P67-3NUS), entitled “HIGH EFFICIENCY SOLAR PANEL,” by inventors Bobby Yang, Peter P. Nguyen, Jiunn Benjamin Heng, Anand J. Reddy, and Zheng Xu, filed Dec. 8, 2014, the disclosure of which is incorporated by reference in its entirety herein.

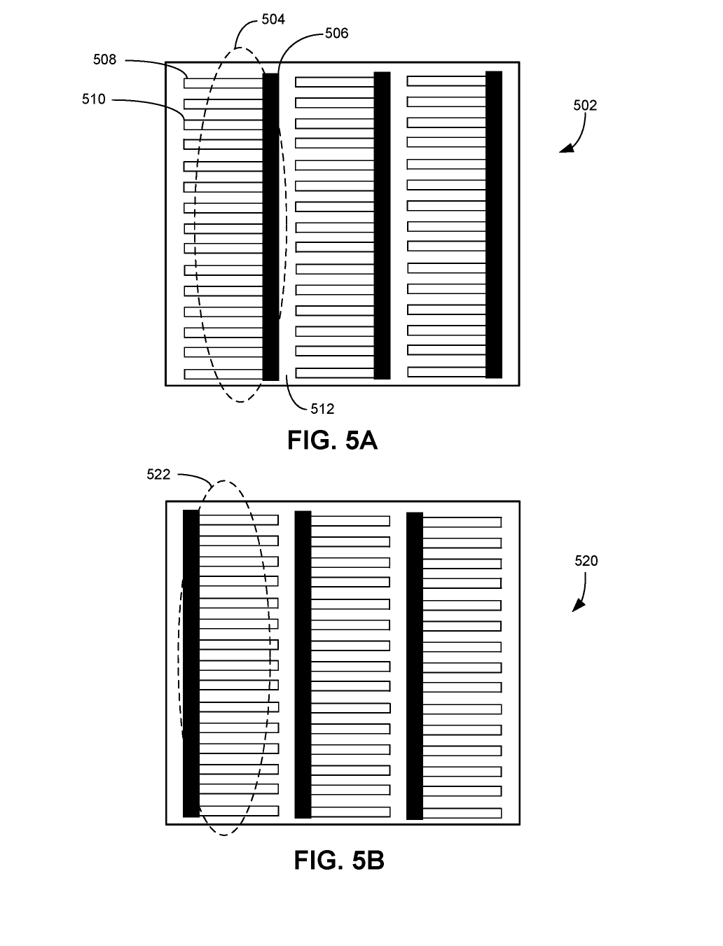

FIG. 5A shows an exemplary metallic grid pattern on the front surface of a solar cell, according to an embodiment of the present invention. In the example shown in FIG. 5A, metallic grid 502 includes three sub-grids, such as sub-grid 504. Each sub-grid is designed to be the front-side grid for the corresponding strip. Hence, the three sub-grid configuration allows the solar cell to be divided into three strips. Various types of metal grid patterns can be used for each sub-grid, such as a conventional grid pattern with double busbars, a single center busbar grid pattern, a single edge busbar grid pattern, etc. In the example shown in FIG. 5A, the sub-grids can have a single edge busbar pattern. Each sub-grid can include an edge busbar along the longer edge of the corresponding strip and a plurality of finger lines along a direction substantially parallel to the shorter edge of the strip. For example, sub-grid 504 can include edge busbar 506, and a plurality of finger lines, such as finger lines 508 and 510. To facilitate the subsequent laser-based scribe-and-cleave process, a predefined blank space (with no metal deposition) can be placed between the adjacent sub-grids. For example, blank space 512 can separate sub-grid 504 from its adjacent sub-grid. In some embodiments, the width of the blank space, such as blank space 512, can be between 0.5 mm and 2 mm. Note that there is a tradeoff between a wider space that leads to an easier scribing operation and a narrower space that leads to more effective current collection. In a further embodiment, the width of such a blank space can be approximately 1 mm.

FIG. 5B shows an exemplary metallic grid pattern on the back surface of a solar cell, according to an embodiment of the present invention. In the example shown in FIG. 5B, back metal grid 520 includes three sub-grids, such as a sub-grid 522. Note that for the strip to be bifacial, the backside sub-grid can correspond to the front-side sub-grid. In this example, the front-side sub-grid can have a single edge busbar grid pattern. Hence, the corresponding backside sub-grid, such as sub-grid 522, can also have an edge busbar pattern. The front and backside sub-grids can have similar patterns except that the front and back edge busbars are located adjacent to opposite edges of the strip. In the example shown in FIGS. 5A and 5B, the front edge busbar can be located at one edge of the front surface of the strip, and the back edge busbar can be located at the opposite edge of the back surface of the smaller cell. In addition, the locations of the blank spaces in back metallic grid 520 can correspond to locations of the blank spaces in front metallic grid 502, such that the Cu grid lines do not interfere with the subsequent wafer-cutting process.

### Electroplating Apparatus

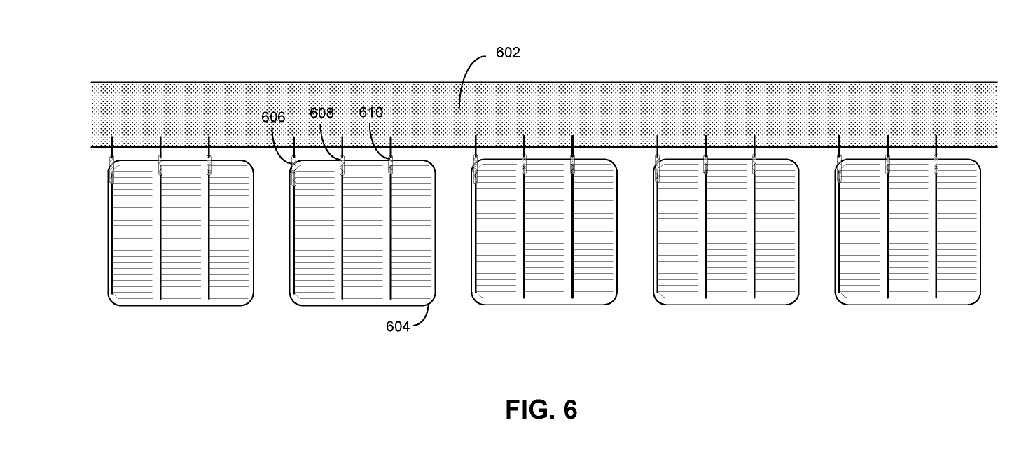

As mentioned above, for cascaded configuration of solar cell strings, a pseudo-square wafer typically would have a number of strips, and each strip can have a single-edge-busbar electrode configuration. FIG. 6 shows an electroplating system according to an embodiment of the present invention. In this example, belt 602, which can be metallic, holds a number of wafers and move these wafers through an electroplating bath. Each wafer can be held by three holding mechanisms. For example, wafer 604 can be held by holding mechanisms 606, 608, and 610. A holding mechanism can provide two functions: to hold the wafer stable during its travel through the electroplating bath, and to provide the electrical connectivity to allow the current to pass to the wafer. In general, a holding mechanism typically holds the wafer at a location where the busbar is, so that the regions where the busbar and finger lines are located can be plated with the metal ions in the bath.

Typically, the wafers have a pseudo-square shape with chamfered corners. This means that the busbar that is located near a wafer edge is likely to be shorter than the others that are no located near an edge. In the example shown in FIG. 6, the left-most busbar on wafer 604 is shorter than the other two busbars. This particular busbar configuration can make conventional wafer-holding mechanisms less suitable, because these holding mechanisms generally have the same dimension. Note that most existing wafer-holding mechanisms are made as small as possible to minimize the obstruction the movement of metal ions in the electroplating bath. As a result, such conventional holding mechanisms might not extend sufficiently to maintain a secure contact with an edge busbar on a wafer.

In embodiments of the present invention, a holding mechanism that has a longer extension can be used for the edge busbar, wherein holding mechanism with a shorter extension can be used for the non-edge busbars in the middle of the wafer. As shown in the example in FIG. 6, holding mechanism 606 can be longer than holding mechanisms 608 and 610, and therefore can maintain a secure physical and electrical contact with the left-most busbar.

In the case where bi-facial solar cells are being fabricated, wafer 604 can have a similar busbar and finger line configuration on the other side (facing away from the viewer). The busbars on the other side can be positioned at a respective opposite edge of the corresponding strip as compared with the busbars on the visible side. In this case, three more wafer holding mechanisms can be used to maintain contact with the busbars on the non-visible side.

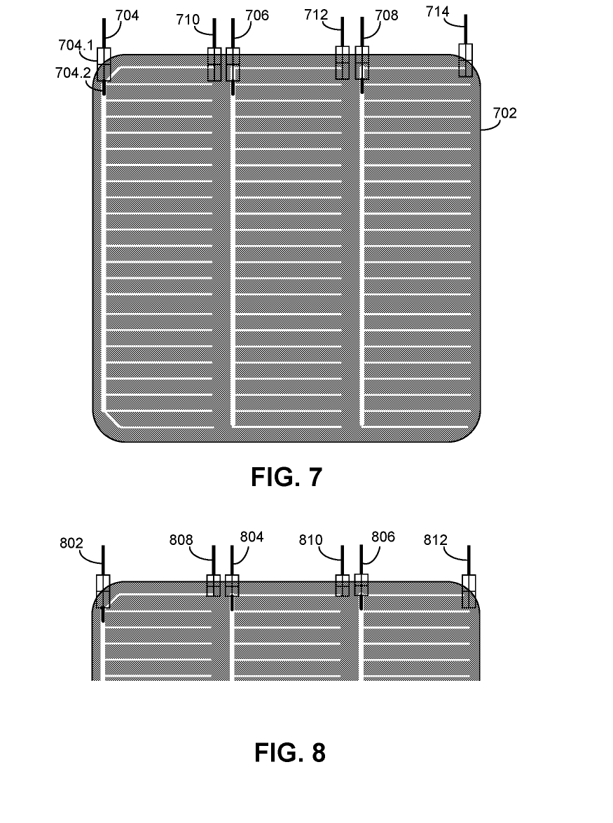

FIG. 7 shows an example of a bifacial solar cell being held by a set of holding mechanisms, according to one embodiment of the present invention. In this example, wafer 702 has a pseudo-square shape, and is covered with patterned photo resist (indicated by the gray shade). The locations where the busbars and finger lines are to be plated are indicated by the color area. Busbars and finger lines are to be deposited on both the front, visible side (the side facing the viewer) and back, non-visible side (the side facing away from the viewer). A first set of holding mechanisms 704, 706, and 708, which are of equal, sufficient length, are used to maintain a contact with the busbars on the visible front side. Note that in this example, each holding mechanism is of substantially the same length, and is sufficiently long to maintain secure contact with the left-most edge busbar. In addition, a respective holding mechanism may have two portions: a spring loading portion, and a contact portion. For example, holding mechanism 704 can have spring loading portion 704.1 and contact portion 704.2. In one embodiment, the spring loading portion can be bent away from the wafer surface, which allows the wafer surface underneath the spring loading portion to be exposed to the ion movement in the electroplating bath. The contact portion can be pushed, by the spring loading portion, against the wafer surface, so that a secure contact can be achieved.

Each of the holding mechanisms 704, 706, and 708 can also have a spring loading portion positioned on the non-visible side, which allows each holding mechanism to function like a clamp. In one embodiment, the spring loading portion on the non-electrical-contact side (which in this example is the non-visible side for holding mechanism 704, 706, and 708) can be covered with an insulating material, so that it does not affect the electroplating and photoresist patterning on the non-visible side. Furthermore, holding mechanisms 704, 706, and 708 can have only a contact portion on the visible side to make contact with the busbar regions. On the non-visible side, these holding mechanisms can have only the spring loading portion.

Similarly, for electroplating on the non-visible side, holding mechanisms 710, 712, and 714 can be used to maintain contact with the busbar regions. The contact portions of these holding mechanisms are on the non-visible side, whereas only insulated spring-loading portions are present on the visible side. This configuration can facilitate double-sided electroplating of solar cell wafers with busbars located near edges with chamfered corners.

FIG. 8 shows another example of a bifacial solar cell being held by a set of holding mechanisms, according to one embodiment of the present invention. In this example, the holding mechanisms are of different lengths. For example, holding mechanism 802 has a longer extension for maintaining secure contact with the left-most busbar, compared with holding mechanisms 804 and 806. In one embodiment, holding mechanism 802's spring loading portion is extended to be longer than those of holding mechanisms 804 and 806. On the non-visible side, a similar set of holding mechanism 808, 810, and 812 are used to maintain contact with the busbars. Holding mechanism 812 can be longer than holding mechanisms 808 and 810 to accommodate the right-most edge busbar (on the non-visible side), which is shorter due to the chamfered corner.

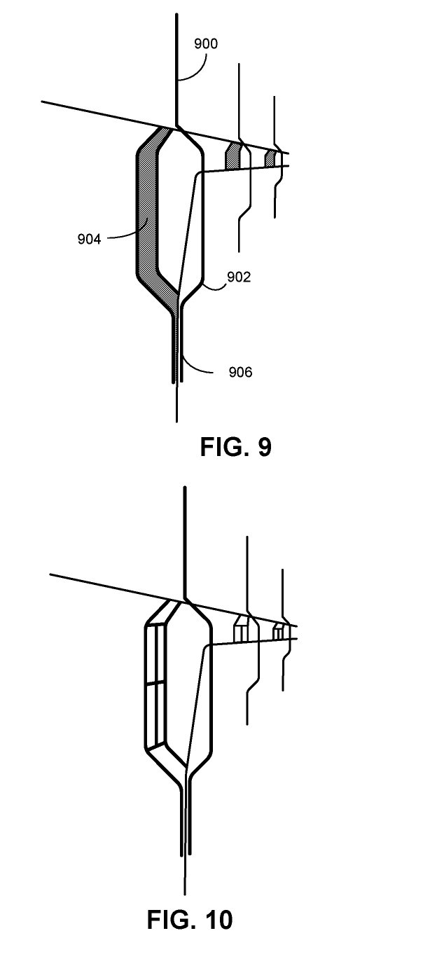

FIG. 9 shows an exemplary holding mechanism, according to an embodiment of the present invention. In this example, holding mechanism 900 can include front spring loading portion 902 and back spring loading portion 904, both of which can be shaped in such a way that they are bent away from the wafer. Front sprint loading portion 902 can be made from a harrow, metallic strip, which can reduce the amount of blocking of ion movement in the electroplating bath. Also, contact portion 906, which is connected to spring loading portion 902, can be made of a similar metallic strip to ensure secure contact with the wafer. In one embodiment, back spring loading portion 904 can be made of sheet metal, metallic wires, or a combination thereof. In addition, back spring loading portion 904 can be coated with a layer of insulating material.

FIG. 10 shows exemplary holding mechanisms, according to an embodiment of the present invention. In this example, the back spring loading portion of a holding mechanism can be a frame made of wires or narrow metallic strips, which can facilitate ion movement. The back spring loading portion can optionally be coated with an insulating material.

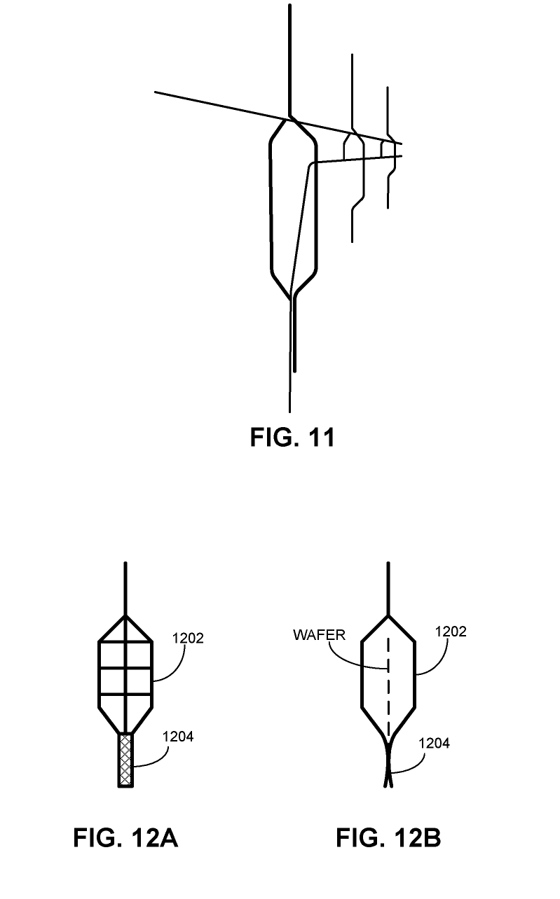

FIG. 11 shows another example of holding mechanisms, according to an embodiment of the present invention. In this example, both the front and back spring loading portions of a holding mechanism can be made of a single metallic or non-metallic strip or wire. This configuration can further reduce the blockage of ion movement during electroplating.

FIG. 12A shows a frontal view of a holding mechanism, and FIG. 12B shows a side view of the holding mechanism, according to one embodiment of an invention. In FIG. 12A, the holding mechanism can have a spring loading portion 1202, which has a shape of a wire frame and can be made of thin metallic strips or wires. Contact portion 1204 can be made of a metal strip to ensure good contact with the area where the busbar is to be deposited. As can be seen in the side view in FIG. 12B, the spring loading portions (both front and back) can be shaped so that they are bent away from the wafer (represented by a dashed line), and contact portion 1204 can be curved outward to ensure a secure contact with the wafer.

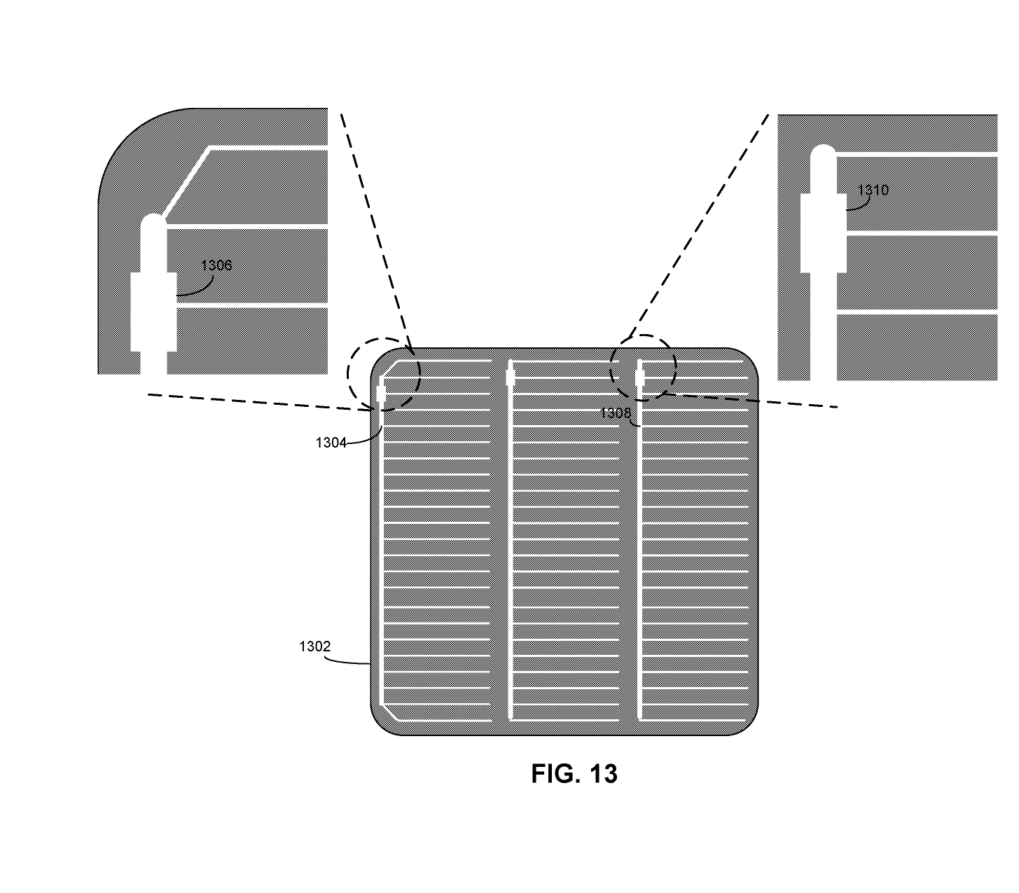

In some embodiments, the photoresist pattern on the wafer can be designed in such a way to accommodate the contact portion of a wafer holding mechanism. FIG. 13 shows an exemplary busbar layout for accommodating the contact of a holding mechanism, according to one embodiment of the present invention. In this example, wafer 1302 has a coat of patterned photoresist (indicated by the gray area), which leaves out certain area that is not covered by photo resist to be plated with metal (indicated by the white area). The left-most busbar area 1304 is near an edge of the wafer, and therefore is shorter than the other busbar areas due to the chamfered corners. To ensure a good contact with the contact portion of a holding mechanism, in one embodiment, busbar 1304 can have enlarged area 1306 to accommodate the contact portion of the wafer-holding mechanism, which can facilitate a more secure physical and electrical contact. Similarly, near the end of busbar area 1308, enlarged contact area 1310 can facilitate a secure contact with the corresponding wafer-holding mechanism.

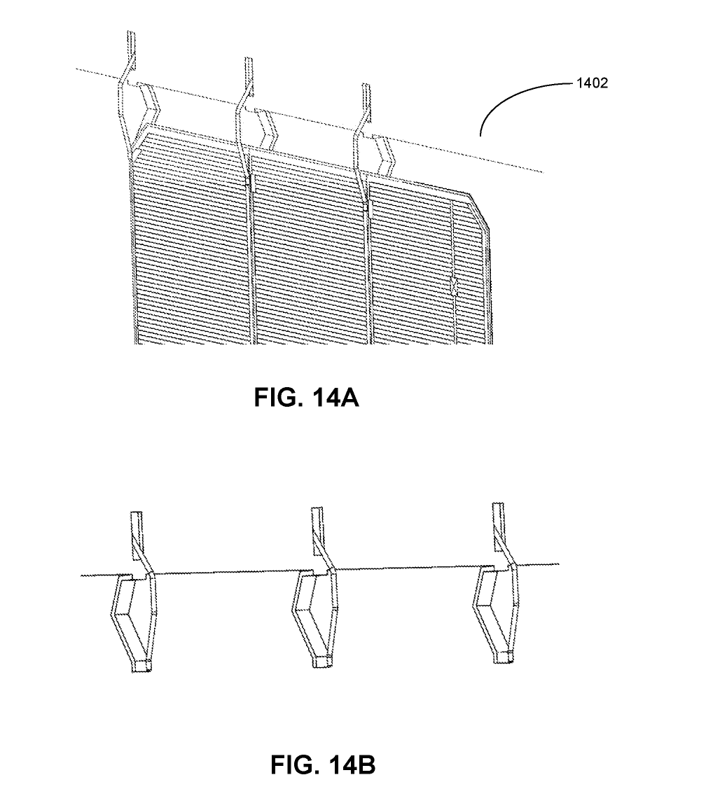

FIG. 14A shows another example of the wafer-holding mechanisms, according to an embodiment of the present invention. In this example, the spring loading portion of each holding mechanism can be made of sheet metal, such as stainless steel, and be part of or attached to belt 1402. FIG. 14B shows another view of the wafer-holding mechanisms shown in FIG. 14A.

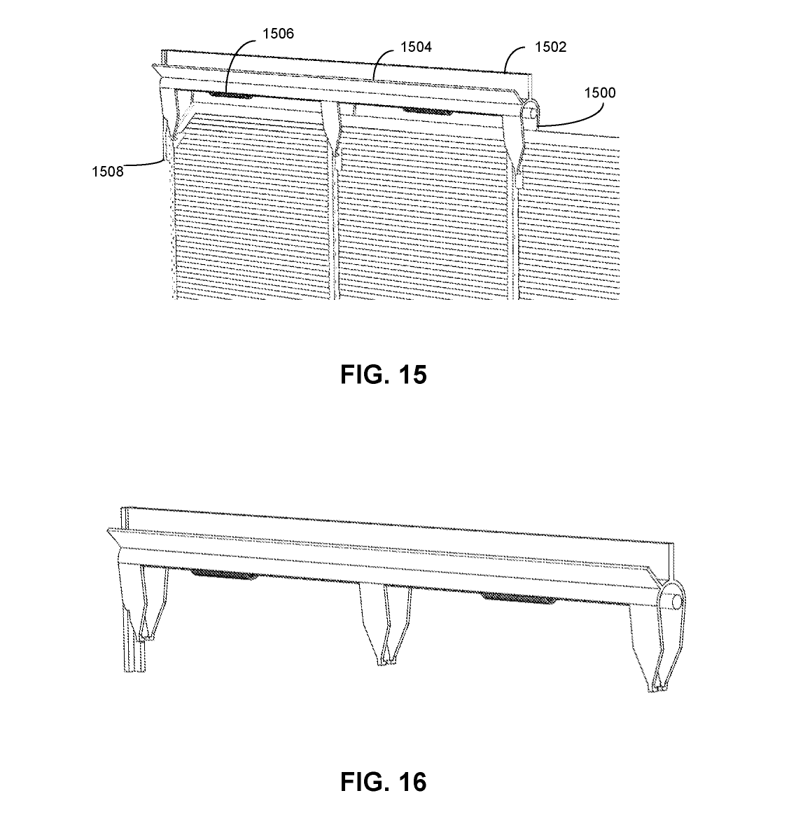

FIG. 15 shows another example of the wafer-holding mechanisms, according to an embodiment of the present invention. In this example, a wafer-holding jig 1500 can include three clamps formed by bent sheet metal. Each clamp has two prongs, and each prong is in contact with one surface of the wafer. These clamps can be opened jointly by tab 1502 and tab 1504. A number of springs, such as spring 1506, can be positioned between tabs 1502 and 1504 to apply a force that opens these clamps. This configuration can allow a worker to affix a wafer to jig 1500 with ease and precision. In addition, jig 1500 can include a stop edge 1508, which can be used to align the wafer, so that each clamp's contact point can be quickly aligned with the contact area on the wafer. FIG. 16 provides another view of the wafer-holding jig shown in FIG. 15.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A wafer-holding apparatus for electroplating of a solar cell wafer, which has chamfered corners and comprises a plurality of busbar areas, wherein at least one busbar area is near an edge of the wafer, the apparatus comprising:
a plurality of wafer-holding mechanisms for maintaining contact with a wafer;
wherein one of the plurality of wafer-holding mechanisms is longer than at least one other wafer-holding mechanism, thereby facilitating secure contact with the busbar area near the edge of the wafer, which is shorter than other busbar areas on the wafer due to the chamfered corners.

2. The wafer-holding apparatus of claim 1, wherein a respective wafer-holding mechanism comprises a spring-loading portion and a contact portion.

3. The wafer-holding apparatus of claim 2, wherein the spring-loading portion is bent away from the wafer.

4. The wafer-holding apparatus of claim 2, wherein the spring-loading portion comprises at least one opening to facilitate electroplating.

5. The wafer-holding apparatus of claim 1, wherein a respective wafer-holding mechanism has a first portion and a second portion;
wherein the first portion is configured to be in contact with a first surface of the wafer; and
wherein the second portion is configured to be in contact with a second surface of the wafer.

6. The wafer-holding apparatus of claim 5,
wherein the first portion is electrically coupled to the first surface of the wafer; and
wherein the second portion is electrically insulated from the second surface of the wafer.

7. The wafer-holding apparatus of claim 1, wherein each wafer-holding mechanism comprises a front spring loading portion and a back spring loading portion; and
wherein the front or back spring loading portion comprises a metallic or non-metallic strip or wire.

8. The wafer-holding apparatus of claim 1, wherein the front or back piece comprises a spring-loading portion, which comprises sheet metal.

9. A wafer-holding apparatus for electroplating of a solar cell wafer, comprising:
a plurality of wafer-holding mechanisms for holding and maintaining contact with the wafer;
wherein the wafer-holding mechanism are of substantially equal length;
wherein a respective wafer-holding mechanism has a front piece and a back piece configured to be in contact with a front surface and a back surface of the wafer, respectively; and
wherein the front piece of the wafer-holding mechanism is narrower than the back piece.

10. The wafer-holding apparatus of claim 9, wherein the front piece comprises a spring-loading portion and a contact portion.

11. The wafer-holding apparatus of claim 10, wherein the spring-loading portion is bent away from the wafer.

12. The wafer-holding apparatus of claim 10, wherein the spring-loading portion comprises at least one opening to facilitate electroplating.

13. The wafer-holding apparatus of claim 9, wherein the front piece is electrically coupled to the front surface of the wafer; and
wherein the back piece is electrically insulated from the back surface of the wafer.

14. The wafer-holding apparatus of claim 9, wherein the front or back piece comprises a spring-loading portion that is a metallic or non-metallic strip or wire.

15. The wafer-holding apparatus of claim 9, wherein the front or back piece comprises a spring-loading portion, which comprises sheet metal.

16. A wafer-holding apparatus for electroplating of a solar cell wafer, comprising:
a plurality of wafer-holding mechanisms for holding and maintaining contact with the wafer, each wafer-holding mechanism having a wafer clamp;
a first tab; and
a second tab;
wherein the first tab is connected to the clamps on a first side;
wherein the second tab is connected to the clamps on a second side; and
wherein the first tab and second tab are coupled by at least one spring, thereby allowing the clamps to be opened together.

17. The wafer-holding apparatus of claim 16, wherein each clamp comprises a first prong and a second prong.

18. The wafer-holding apparatus of claim 17, wherein the first prong is connected to the first tab, and second prong is connected to the second tab.

19. The wafer-holding apparatus of claim 16, further comprising a spring mechanism between the first tab and second tab.

20. The wafer-holding apparatus of claim 16, further comprising an edge stop positioned on one side of the wafer-holding mechanisms, thereby facilitating alignment of the wafer with the wafer-holding mechanisms.
